(19) United States
(12) Patent Application Publication
(10) Pub. No.: US 2002/0001975 A1
(43) Pub. Date: Jan. 3, 2002

(54) Method of generating a circuit pattern used for fabricating a semiconductor device

(76) Inventor: Dae-Youp Lee, Kunpo-shi (KR)

Correspondence Address: The Law Offices of Eugene M Lee, PLLC, 2111 Wilson Boulevard, Suite 1200, Arlington, VA, 22201, US

(21) Appl. No.: 09/867,457

(22) Filed: May 31, 2001

(30) Foreign Application Priority Data
May 31, 2000 (KR) 29548/2000

(51) Int. Cl. H01L 21/324

(52) U.S. Cl. 438/795

(57) ABSTRACT

A method of generating a circuit pattern of a semiconductor device, comprises sequentially depositing a first patternable layer and photoresist layer, converting a given depth of the photoresist layer into a second patternable layer insoluble in an alkaline solution, selectively etching the second patternable layer to form a photoresist pattern mask, applying an O₂ plasma through the photoresist pattern mask to form a photoresist pattern in the unconverted part of the photoresist layer, and selectively etching the first patternable layer by using the photoresist pattern as a mask to obtain a fine circuit pattern.

### BACKGROUND OF THE INVENTION

1. Field of the Invention

The present invention relates to a semiconductor device. More particularly, the present invention relates to an improved method of generating a circuit pattern of high resolution used for fabricating a semiconductor device.

2. Description of Background Art

It has taken significant advancements in semiconductor technology even to fabricate 1 G DRAM to store 1-gigabit information in a single chip. This technology requires that the size of each single memory cell be about 0.3 μm². Accordingly, extreme measures must be taken to generate the circuit pattern to accommodate for such a small device size.

Also in such technology, the photolithography also requires a new material for the resist. Especially, as the integration scale has been enhanced from 256 M DRAM to the order of 1 G, the wavelength region of the light source has been shifted from the region of DUV (Deep UV: 248 nm) to that of ArF (193 nm), for which the ArF eximer laser has been proposed as the light source. Hence, there is a serious need to develop a new resist for use in a region of a shorter wavelength than that of 248 nm.

The resist suitable for ArF must have transparency in the region of 193 nm, good durability against the etching process, refractoriness, and good adhesiveness. In addition, as the wavelength of the light source becomes shorter, a new photolithographic technology has been proposed. In this technique, a chemically amplified resist of high sensitivity and high resolution is used, which when exposed to light, generates proton H⁺ serving as a catalyst to make chain reactions of diffusing H⁺ and depolymerization, so as to form the circuit pattern while maintaining a high transparency.

Meanwhile, since the photoresist pattern generated by the photolithography is widely used as a mask for etching, ion-implantation, etc. during the process of fabricating a semiconductor device, it must be precisely formed, stabilize the fabrication process, be completely removed after the fabrication process, and facilitate remaking if there is a failure.

In the photolithography, the photoresist is prepared by dissolving a photoactive compound (PAC) and an alkaline-soluble resin in a suitable solvent. Then, the photoresist is uniformly applied to a semiconductor substrate by spinning, and subjected to a soft baking process at a low temperature. Next, a pattern mask is used to selectively harden the photoresist layer by exposing it to light, and then the semiconductor substrate having the exposed photoresist layer is subjected to a post exposure baking (PEB). Finally, the photoresist is treated by tetramethylammoniumhydroxide (TMAH) to selectively remove the parts not hardened, thus forming a photoresist pattern.

However, the photolithography, which depends on a wet process as described above, suffers a drawback in that the photoresist pattern, which is formed on the sub-micron scale in a high-density circuit, may be erased. Therefore, the photoresist layer is covered with an upper layer containing Si, Ge, etc. in order to prevent such erasure. Subsequently, the photoresist layer is subjected to a top surface imaging (TSI) process by using oxide plasma to etch the pattern. Such TSI process using the upper layer containing Si is generally called DESIRE (diffusion enhanced silylated resist).

FIGS. 1A to 1C illustrate the conventional process of generating a pattern to fabricate a semiconductor device. Referring to FIG. 1A, a lower layer 2 deposited on a semiconductor substrate (not shown) is covered with a photoresist 3 by spinning to form a pattern. Prior to deposition on the substrate, the photoresist is prepared by dissolving a PAC and a resin in a suitable solvent.

Then, the substrate covered with the photoresist 3 is treated by a soft baking process, and the photoresist 3 is selectively exposed to an ultra-violet short wavelength eximer laser, having a wavelength of 248 nm. The photoresist 3 is then exposed to an organic metal compound containing Si to substitute Si in place of the H of the hydroxide contained in the photoresist 3, which is the silylation. Referring now to FIG. 1B, the photoresist 3 is selectively removed by an alkaline developing agent according to the dissolvent difference between the parts exposed to light and the parts not exposed to light. In addition, an upper layer 4 containing Si, which is durable against Oplasma due to the silylation of the photoresist, is generated. Then, the semiconductor substrate is subjected to PEB, and the upper layer 4 is used as the mask to obtain a photoresist pattern 3a, by selectively etching into the parts of the surface not containing Si, by O₂ plasma.

Referring to FIG. 1C, the photoresist pattern 3a, which serves as the mask for subsequent etching and ion-implantation processes, is then removed by using an O₂ plasma, or an organic or organic acid solvent. However, the organic or organic acid solvent may damage a particular layer on the substrate, such as a metal layer, and the O₂ plasma may damage the other parts along with the photoresist pattern 3a. In addition, the upper layer of SiO₂ formed over the photoresist pattern is not completely removed, thereby leaving a residue 5. Moreover, the critical dimension (CD) should be reduced for a highly integrated device, requiring upgrading of the equipment for fabricating the semiconductor devices, and hence increasing the cost. Furthermore, the phase shift mask (PSM) and resist flow process are used to improve the resolution of the pattern, but they do not provide sufficiently high resolution, thus requiring additional processes, and may be only applied to a particular layer.

Accordingly, the conventional method for fabricating a semiconductor device by using the TSI process has a disadvantage in that the upper layer containing Si, Ge, etc. is not effectively removed, thereby leaving a residue after removal of the used or failing photoresist. If the output of the O₂ plasma is increased, or the organic or organic acid solvent is used excessively to completely remove the residue, the surface of the semiconductor substrate or a particular layer on the substrate, such as a metal layer, is damaged thereby degrading the reliability of the semiconductor device.

### SUMMARY OF THE INVENTION

It is a feature of an embodiment of the present invention to provide a method of generating a circuit pattern used for fabricating a semiconductor device without requiring an additional high cost upgrade or new fabrication equipment.

According to an aspect of an embodiment of the present invention, a method of generating a circuit pattern of a semiconductor device, comprises sequentially depositing a first patternable layer and photoresist layer, converting a given depth of the photoresist layer into a second patternable layer insoluble in an alkaline solution when not exposed to light, selectively etching the second patternable layer to form a photoresist pattern mask, applying O₂ plasma through the photoresist pattern mask to form a photoresist pattern in the underlying unconverted, photoresist layer, and selectively etching the first patternable layer by using the photoresist pattern as a mask to obtain a fine circuit pattern.

Preferably, the photoresist layer is prepared by mixing an alkali soluble resin and a PAG. The alkali soluble resin may be polyvinyl chloride phenol or novolak. The molecular weight of polyvinyl chloride phenol is 1.000 to 30.000 g/mole and its dispersion degree is 1.3 to 4.0. Likewise, the molecular weight of novolak is 1.000 to 25.000 g/mole, and its dispersion degree is 2.0 to 5.5.

Preferably, forming a photoresist pattern mask further comprises exposing the second patternable layer to light of low energy, subjecting it to a post exposure baking (PEB), and developing it in an alkaline solution. Developing is performed by using tetra-methylammonium hydroxide of 0.1 normality for 28 to 32 seconds. Converting the top part of the photoresist layer into a second patternable layer further comprises exposing the photoresist layer to a reacting gas at a temperature of 100 to 130° C. The thickness of the photoresist is 0.7 to 1.0 μm.

These and other features of the present invention will be readily apparent to those of ordinary skill in the art upon review of the detailed description that follows and the attached drawings.

### BRIEF DESCRIPTION OF THE DRAWINGS

FIGS. 1A to 1C are cross-sectional views illustrating a conventional method of generating a circuit pattern of a semiconductor device according to the prior art; and

FIGS. 2A to 2D are cross-sectional views illustrating a method of generating a circuit pattern of a semiconductor device according to an embodiment of the present invention.

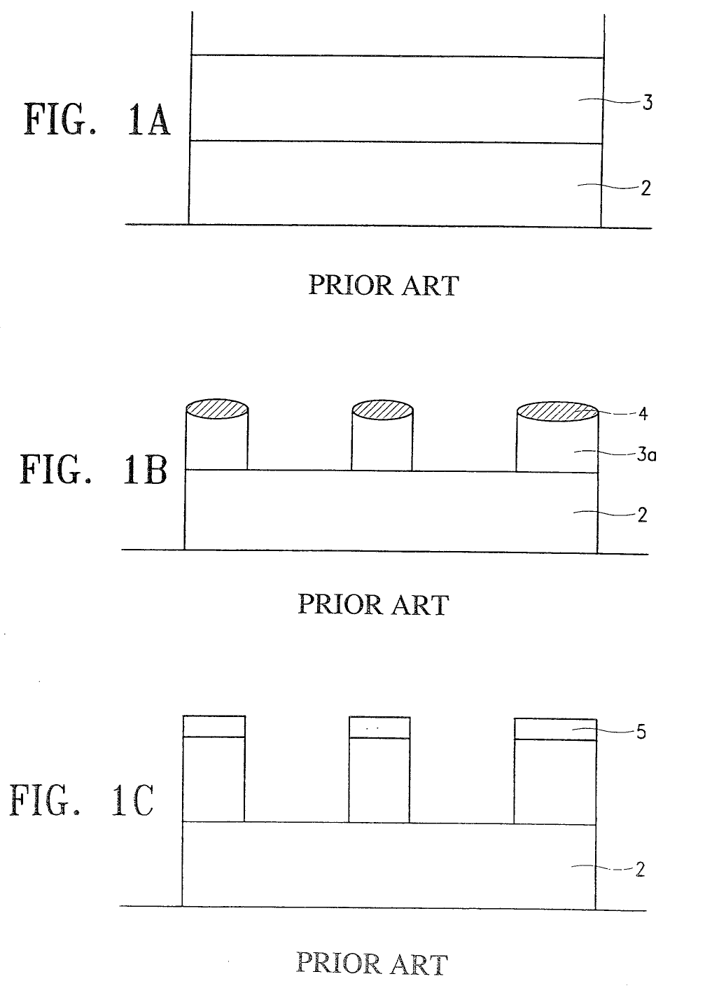

### DETAILED DESCRIPTION OF THE PREFERRED EMBODIMENTS

Korean Patent Application No. 00-29548, filed May 31, 2000, and entitled: “Method of Generating a Circuit Pattern Used for Fabricating a Semiconductor Device,” is incorporated by reference herein in its entirety.

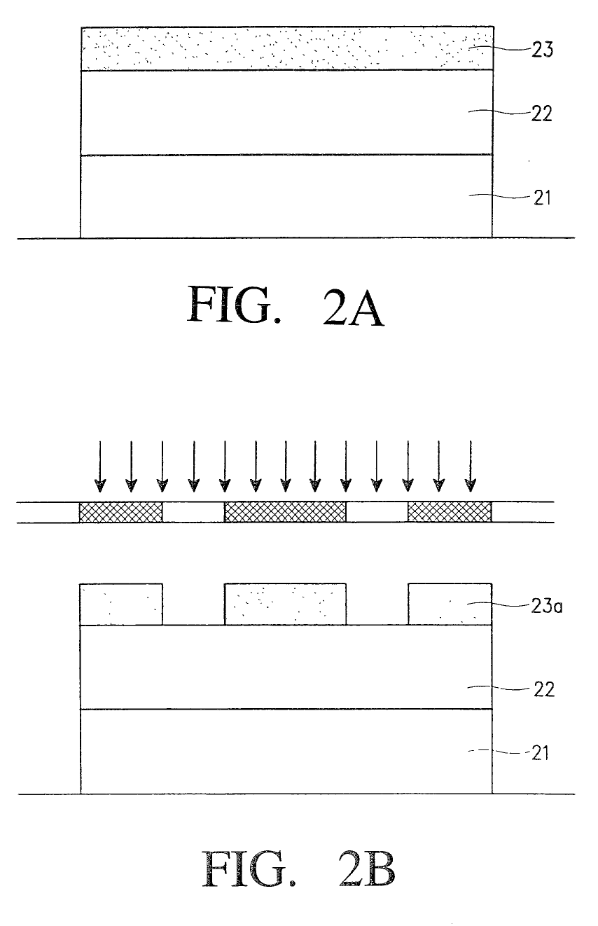

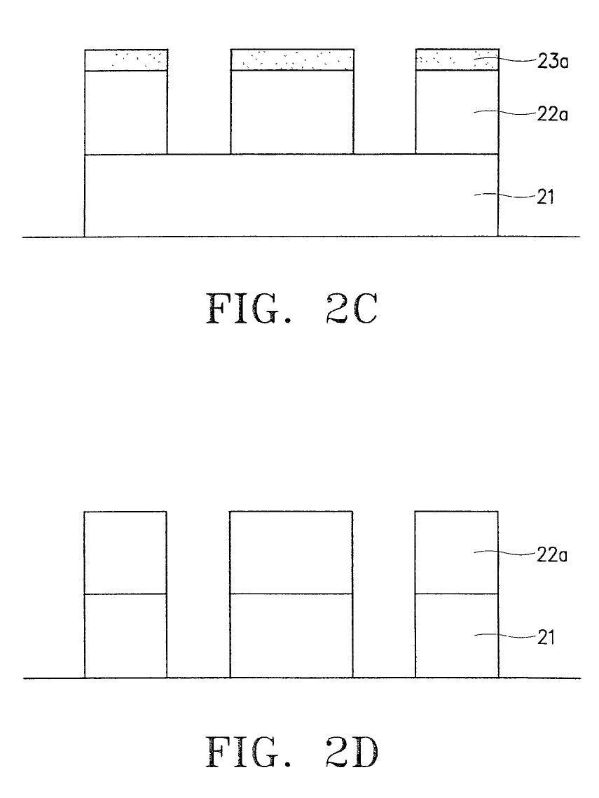

Referring to FIG. 2A, a first patternable layer 21 and a photoresist layer 22 are sequentially deposited over a semiconductor substrate (not shown). The photoresist layer 22 is prepared by dissolving a mixture of a resin soluble in an akali and photo acid generator (PAG) in ethyl lactate (EL). The thickness of the photoresist layer is preferably 0.7 to 1.0 μm. In the present invention, the first patternable layer 21 is preferably composed of dimethyl silane group, and the resin soluble in an akali preferably may be polyvinyl chloride phenol resin or novolak.

According to a first embodiment of the present invention, the photoresist layer 22 is subjected to a reaction with a gas such as hexamethyldisilane (HMDS) or tetramethyldisilane (TMDS) at a temperature of 100 to 130° C. to form a second protective patternable layer 23 that contains silicon and is insoluble in an alkaline solution. In this case, the reactive mechanism by TMDS is expressed by the following formula:

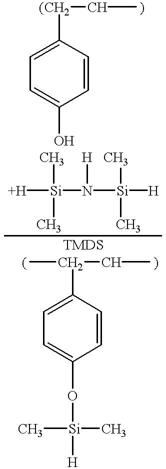

wherein the molecular weight of the polyvinyl chloride in the photoresist layer is 1.000 to 30.000 g/mole, and its dispersion degree is 1.3 to 4.0.

According to a second embodiment of the present invention, the photoresist layer is reacted with a liquid composed of bi-dimethylamine-methylsilane (B(DMA)MS), tetra-methylsilanedimethylamine (TMSDMA), and dimethylsilanedimethylamine (DMSDMA) to form a second protective patternable layer 23 that contains silicon and is insoluble in an alkaline solution. In this case, the reactive mechanism by B(DMA)MS is expressed by the following formula:

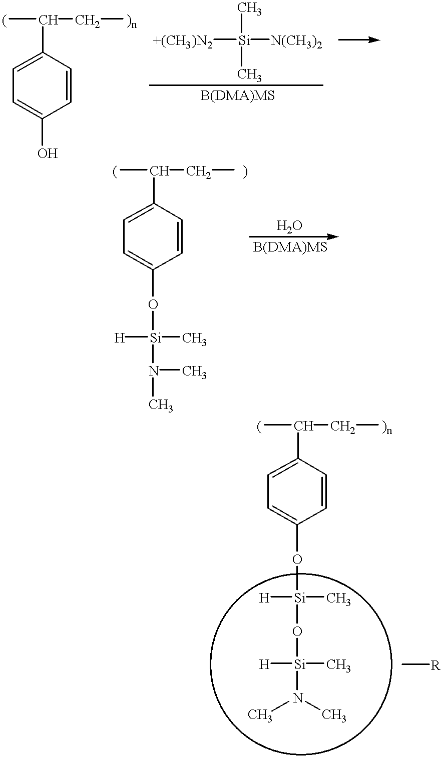

wherein the molecular weight of the polyvinyl chloride in the photoresist layer is 1.000 to 30.000 g/mole, and its dispersion degree is 1.3 to 4.0. H₂O could not react with the dimethyl amine group to create a new —OH group, and B(DMA)MS reacts with the —OH group.

According to a third embodiment of the present invention, the photoresist layer using polyvinyl chloride phenol as the resin substituted with 0 to 20% of the tetra-butyloxy carbonyl groups is subjected to a reaction with a gas such as HMDS or TMDS at a temperature of 100 to 130° C. to form a second protective patternable layer that contains silicon and is insoluble in an alkaline solution. In this case, the reactive mechanism by TMDS is expressed by the following formula:

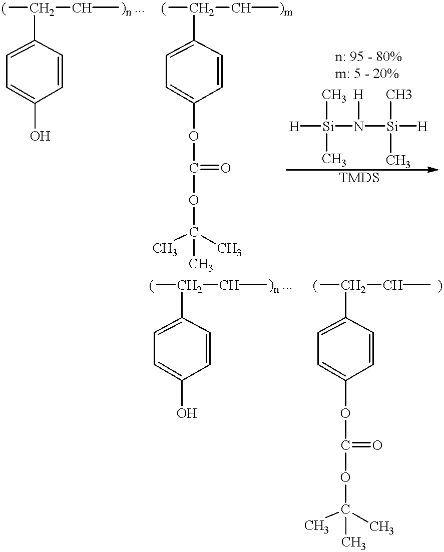

wherein the molecular weight of the polyvinyl chloride phenol substituted with 0 to 20% of the tetra-butyloxy carbonyl groups in the photoresist layer is 1.000 to 30.000 g/mole, its dispersion degree is 1.3 to 4.0, and n is between 95-80% and m is between 5-20%.

According to a fourth embodiment of the present invention, the photoresist layer having novolak as the resin is subjected to a reaction with a gas such as HMDS or TMDS at a temperature of 100 to 130° C. to form a second protective patternable layer that contains silicon and is insoluble in an alkaline solution. In this case, the reactive mechanism by HMDS is expressed by the following formula:

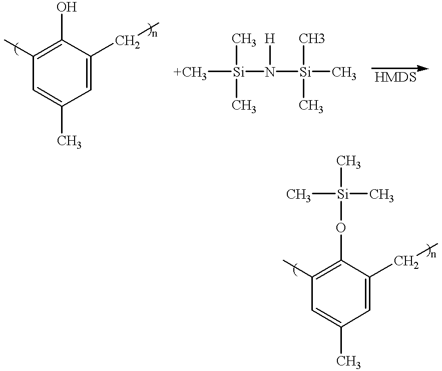

wherein the molecular weight of novolak is 1.000 to 25.000 g/mole, its dispersion degree is 2.0 to 5.5, and n is between 95-80% and m is between 5-20%. Similarly, the reactive mechanism by TMDS is expressed by the following formula:

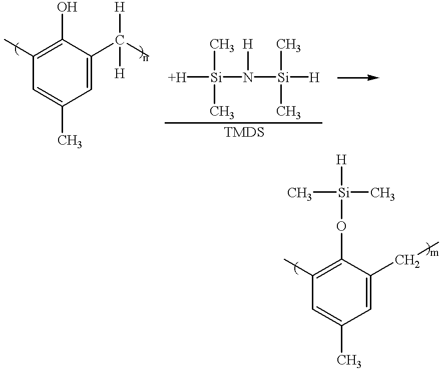

wherein the molecular weight of novolak is 1.000 to 25.000 g/mole, and its dispersion degree is 2.0 to 5.5, and n is between 95-80% and m is between 5-20%. Formation of the second patternable layer 23 may be detected by using FI-IR, and its depth through thermal gravity analysis (TGA).

Referring to FIG. 2B, the photoresist is exposed through a mask to a light source of low energy. Then, the PAG present in the second patternable layer 23 generates acid, and the subsequent PEB process causes the protective Si group to undergo a deprotection reaction substituted by a hydroxyl group OH. Developing the second patternable layer in a developing agent such as tetramethylaminohydroxide (TMAH) of 0.1 normality for 28 to 32 seconds generates a fine resist pattern 23a. Then, its threshold size (critical dimension (CD)) is measured. In this case, the reaction mechanism using the PAG as in the first embodiment is expressed by the following formula:

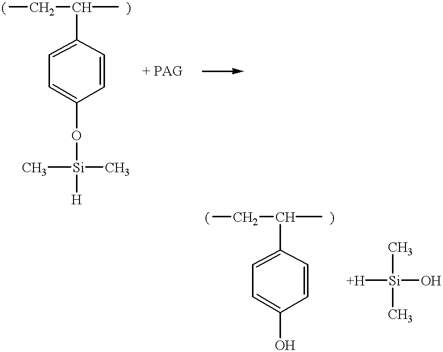

In addition, the reaction mechanism using the PAG as in the second embodiment is expressed by the following formula:

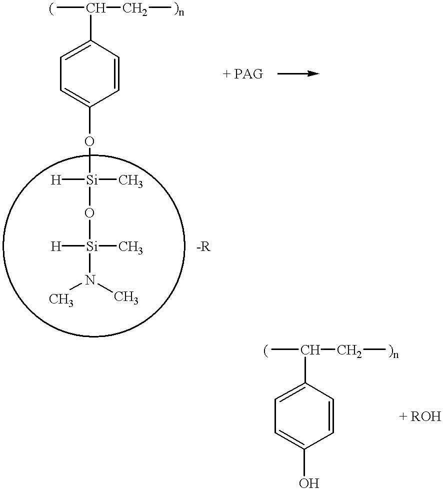

Further, the reaction mechanism using the PAG as in the third embodiment is expressed by the following formula:

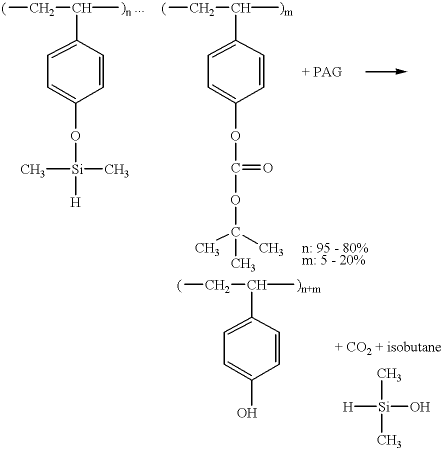

Still further, the reaction mechanism using the PAG with TMDS as in the fourth embodiment is expressed by the following formula:

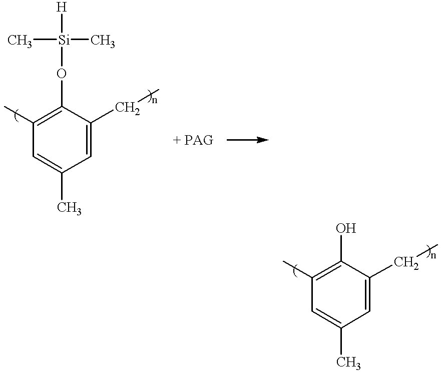

Additionally, the reaction mechanism using the PAG with HMDS as in the fourth embodiment is expressed by the following formula:

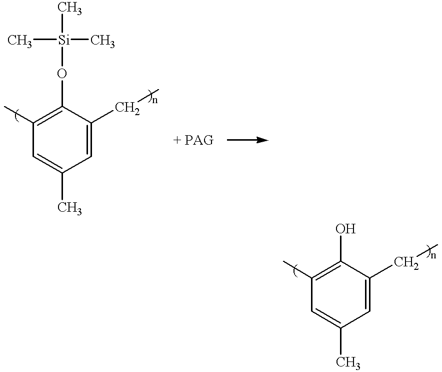

Then, O₂ plasma is applied through the photoresist pattern mask 23a to selectively etch the photoresist layer 22 to obtain the photoresist pattern 22a, as shown in FIG. 2C. As described above, the silylation enhances the selectivity to the O₂ plasma, so that etching resistance is provided enough to generate a fine circuit pattern. After removing the upper photoresist pattern mask 23a as shown in FIG. 2D, the photoresist pattern 22a is used as the mask to subject the lower first patternable layer 21 to dry etching. Finally, the photoresist pattern 22a is removed to obtain the fine circuit pattern.

Thus, the inventive method provides a means for generating a fine circuit pattern at a low cost, without replacing or upgrading the conventional semiconductor fabrication equipment. In addition, the method of the present invention does not require a coating or deposition of organic or inorganic ARL, which is widely used as the anti-reflective layer, without producing the lower layer dependability. Further, it resolves the difficulties of the R/W process caused by the difficulties inherently accompanying measurement of the threshold size and checking of M/A after forming the circuit pattern.

While the present invention has been described in connection with preferred embodiments accompanied by the attached drawings, it will be readily apparent to those of ordinary skill in the art that various changes and modifications may be made thereto without departing from the spirit and scope of the present invention.

What is claimed is:

1. A method of generating a circuit pattern of a semiconductor device, comprising:
sequentially depositing a first patternable layer and photoresist layer;
converting a given depth of said photoresist layer into a second patternable layer insoluble in an alkaline solution;
selectively etching said second patternable layer to form a photoresist pattern mask;
applying an O₂ plasma through said photoresist pattern mask to form a photoresist pattern in the unconverted part of the photoresist layer; and
selectively etching said first patternable layer by using said photoresist pattern as a mask to obtain a fine circuit pattern.

2. The method as defined in claim 1, wherein said second patternable layer is obtained by subjecting said photoresist layer to a reaction with a gas such as hexamethyldisilane (HMDS) or tetramethyldisilane (TMDS) at a temperature of 100 to 130° C.

3. The method as defined in claim 1, wherein said photoresist layer is prepared by mixing an alkali soluble resin and photo-acid generator (PAG).

4. The method as defined in claim 3, wherein said alkali soluble resin is selected from the group of polyvinyl chloride phenol and novolak.

5. The method as defined in claim 4, wherein said polyvinyl chloride phenol is substituted with 0 to 20% of the tetra-butyloxy carbonyl groups.

6. The method as defined in claim 4, wherein the molecular weight of said polyvinyl chloride phenol or that substituted with 0-20% of tetra-butyloxy carbonyl groups is 1.000 to 30.000 g/mole.

7. The method as defined in claim 4, wherein the dispersion degree of said polyvinyl chloride phenol or that substituted with 0-20% of tetra-butyloxy carbonyl groups is 1.3 to 4.0.

8. The method as defined in claim 4, wherein the molecular weight of said novolak is 1.000 to 25.000 g/mole.

9. The method as defined in claim 4, wherein the dispersion degree of said novolak is 2.0 to 5.5.

10. The method as defined in claim 1, wherein forming said photoresist pattern mask further comprises:
exposing said second patternable layer to light of low energy;
subjecting said second patternable layer to post exposure baking (PEB); and
developing said second patternable layer in an alkaline solution.

11. The method as defined in claim 10, wherein developing is performed by using tetra-methylammonium hydroxide of 0.1 normality for 28 to 32 seconds.

12. The method as defined in claim 1, wherein converting a given depth of said photoresist layer into a second patternable layer insoluble in an alkali comprises reacting said photoresist layer composed of polyvinyl chloride phenol with a gas such as HMDS or TMDS.

13. The method as defined in claim 1, wherein converting a given depth of said photoresist layer into a second patternable layer insoluble in an alkali comprises reacting said photoresist layer composed of polyvinyl chloride phenol with a liquid composed of bi-dimethylamine-methylsilane (B(DMA)MS), tetra-methylsilanedimethylamine (TMSDMA), and dimethylsilanedimethylamin (DMSDMA).

14. The method as defined in claim 1, wherein converting a given depth of said photoresist layer into a second patternable layer insoluble in an alkali comprises reacting said photoresist layer composed of novolak with a gas such as HMDS or TMDS.

15. The method as defined in claim 12, wherein reacting said photoresist layer with said gas is performed at a temperature of 100 to 130° C.

16. The method as defined in claim 1, wherein the thickness of the photoresist is 0.7 to 1.0 μm.

17. The method as defined in claim 5, wherein said second patternable layer is obtained by reacting said photoresist layer with a gas such as hexamethyldisilane (HMDS) or tetramethyldisilane (TMDS) at a temperature of 100 to 130° C.

18. The method as defined in claim 1, wherein the selective etching of the second patternable layer is performed by developing the second patternable layer in a developing agent such as tetramethylaminohydroxide (TMAH).

19. The method as defined in claim 18, wherein the tetramethylaminohydroxide (TMAH) is of 0.1 normality.

20. The method as defined in claim 19, wherein developing the second patternable layer in tetramethylaminohydroxide (TMAH) is performed for 28 to 32 seconds.

21. The method as defined in claim 5, wherein the molecular weight of said polyvinyl chloride phenol or that substituted with 0-20% of tetra-butyloxy carbonyl groups is 1.000 to 30.000 g/mole.

22. The method as defined in claim 5, wherein the dispersion degree of said polyvinyl chloride phenol or that substituted with 0-20% of tetra-butyloxy carbonyl groups is 1.3 to 4.0.
